(19) United States
(12) Patent Application Publication
(10) Pub. No.: US 2010/0246560 A1
(43) Pub. Date: Sep. 30, 2010

(54) METHOD OF COMMUNICATING WITH USER COOPERATION AND TERMINAL DEVICE OF ENABLING THE METHOD

(75) Inventor: Jun Mo KIM, Yongin-si Gyeonggi-do (KR)

Correspondence Address: North Star Intellectual Property Law, PC, P.O. Box 34688, Washington, DC, 20043, US

(73) Assignee: Samsung Electronics Co. Ltd, Suwon-si (KR)

(21) Appl. No.: 12/679,399

(22) PCT Filed: Sep. 17, 2008
(86) PCT No.: PCT/KR2008/005479

§ 371 Date: Jun. 15, 2010

(30) Foreign Application Priority Data
Sep. 21, 2007 (KR) 1020070096919

(51) Int. Cl. H04J 3/00; H03M 13/09; G06F 11/10; H04B 15/00; H04K 1/10

(52) U.S. Cl. 370/345; 714/809; 375/285; 375/260; 714/E11.032

(57) ABSTRACT

Proposed is a user cooperative terminal device. The user cooperative device includes: a signal detector to receive a signal transmitted from a source node and detect a received signal; and a message generator to cancel interference caused by a neighboring user in the received signal, using a neighboring user message, and to generate a user message. The neighboring user may decode a received signal of the neighboring user to transfer the neighboring user message.

### CROSS-REFERENCE TO RELATED APPLICATIONS

The present application claims the benefit of International Patent Application No. PCT/KR2008/005479, filed Sep. 17, 2008, and Korean Patent Application No. 10-2007-0096919, filed Sep. 21, 2007, disclosure of each of which is incorporated herein in its entirety for all purposes.

### TECHNICAL FIELD

One or more embodiments relate to a multi-user Multiple Input Multiple Output (MIMO) communication system, and more particularly, to a user cooperative terminal device for performing communication through cooperation between users, and a user cooperative communication method using the same.

### BACKGROUND ART

Currently, many researches have been conducted to provide various types of multimedia services such as a voice service and supporting enhanced high-speed data transmission in a wireless communication environment. As for a representative example, a research regarding a space division multiple access (SDMA) technology using multiple antennas is in development.

The SDMA technology can transmit at least one data stream to multiple users via a plurality of antennas. The SDMA technology can increase the overall capacity of a communication system by more effectively using radio resources.

Generally, in a closed-loop SDMA system, user terminals can feed back, to a base station, feedback data associated with a channel state. The base station can select a user terminal based on the feedback data to perform beamforming

In this instance, in a circumstance where bits for feedback data are limited, it may be difficult to achieve a high data transmission rate. In particular, interference occurring among the multiple users may cause many disturbances in a communication performance.

Each of the multiple users may be unaware of a channel state of a channel that is formed between the base station and another user or a signal received by the other user. Therefore, each of the multiple users may not easily cancel an interference signal in a received signal and also may not easily detect, in the received signals, only a signal for each corresponding user.

Accordingly, there is a need for a user cooperative terminal device and a user cooperative communication method that can easily cancel an interference signal occurring among multiple users and also can easily detect, in received signals, only a signal for each corresponding user.

### SUMMARY

### Technical Goals

One or more embodiments may provide a user cooperative terminal device and a user cooperative communication method that can cancel interference, caused by a neighboring user, using a neighboring user message that is decoded by the neighboring user to thereby achieve an enhanced data transmission rate.

One or more embodiments also may provide a user cooperative terminal device and a user cooperative communication method that can receive channel information associated with a channel that is formed between a neighboring user and a source node to thereby effectively cancel interference caused by the neighboring user.

One or more embodiments also may provide a user cooperative terminal device and a user cooperative communication method that can optimize a ratio of a first time slot for receiving a signal transmitted from a source node and a second time slot for performing a cooperative communication between users to thereby improve a communication performance.

One or more embodiments also may provide a user cooperative terminal device and a user cooperative communication method that can generate a filter capable of effectively filtering a transferred received signal of a neighboring user and a received signal of a corresponding user to thereby achieve an enhanced data transmission rate.

### Technical Solutions

According to example embodiments, a user cooperative terminal device may include: a signal detector to receive a signal transmitted from a source node and detect a received signal; and a message generator to cancel interference caused by a neighboring user in the received signal, using a neighboring user message and generate a user message, wherein the neighboring user decodes a received signal of the neighboring user to transfer the neighboring user message.

According to other example embodiments, an apparatus for receiving a user cooperative signal may include: a signal detector to receive a signal transmitted from a source node, detect a received signal, and receive a received signal of a neighboring user; a filter generator to generate a filter based on a channel state of a channel that is formed between the neighboring user and the source node; and a filtering unit to filter the received signal and the received signal of the neighboring user via the filter and extract a user signal.

According to still other example embodiments, a user cooperative communication method may include: receiving a signal transmitted from a source node to detect a received signal; and canceling interference caused by a neighboring user in the received signal, using a neighboring user message to generate a user message, wherein the neighboring user decodes a received signal of the neighboring user to transfer the neighboring user message.

According to yet other example embodiments, a method of receiving a user cooperative signal may include: receiving a signal transmitted from a source node to detect a received signal and receiving a received signal of a neighboring user; generating a filter based on a channel state of a channel that is formed between the neighboring user and the source node; and filtering the received signal and the received signal of the neighboring user via the filter to extract a user signal.

### BRIEF DESCRIPTION OF DRAWINGS

FIG. 1 illustrates a multi-user Multiple Input Multiple Output (MIMO) communication system according to example embodiments;

FIG. 2 is a block diagram illustrating a user cooperative terminal device according to example embodiments;

FIG. 3 illustrates an example of an operation between a base station and users in a first time slot and a second time slot according to example embodiments;

FIG. 4 is a block diagram illustrating an apparatus for receiving a user cooperative signal according to example embodiments;

FIG. 5 is a flowchart illustrating a user cooperative communication method according to example embodiments; and

FIG. 6 is a flowchart illustrating a method of receiving a user cooperative signal according to example embodiments.

### BEST MODE

Reference will now be made in detail to example embodiments, examples of which are illustrated in the accompanying drawings, wherein like reference numerals refer to the like elements throughout. The example embodiments are described below in order to explain the present disclosure by referring to the figures.

Hereinafter, example embodiments will be described in detail with reference to the accompanying drawings.

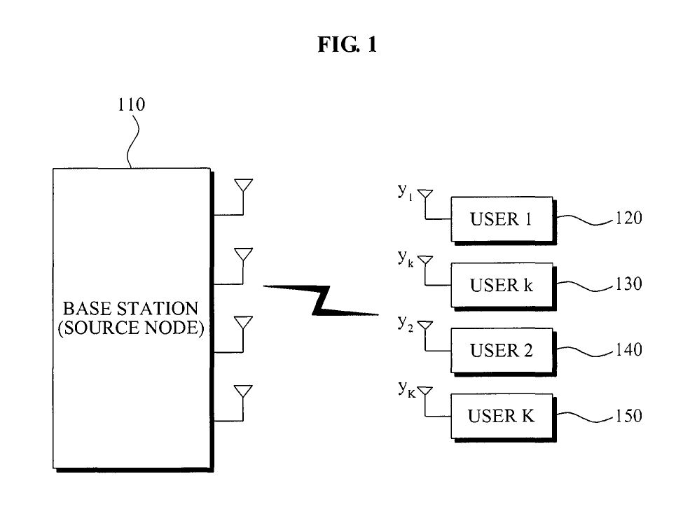

FIG. 1 illustrates a multi-user Multiple Input Multiple Output (MIMO) communication system according to example embodiments.

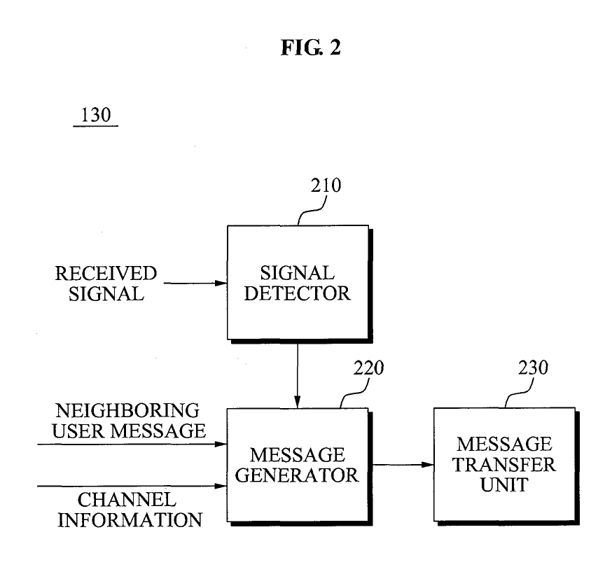

FIG. 2 is a block diagram illustrating a user cooperative terminal device according to example embodiments.

Hereinafter, the user cooperative terminal device will be described with reference to FIGS. 1 and 2.

Referring to FIG. 1, the multi-user MIMO communication system includes a base station 110 corresponding to a source node and a plurality of users (1, k, 2, and K) 120, 130, 140, and 150.

Generally, the base station 110 may generate a transmission signal based on a data stream, using a beamforming vector. The beamforming vector may be selected according to a channel state of a radio channel that is formed between the base station 110 and each of the users (1, k, 2, and K) 120, 130, 140, and 150.

The users (1, k, 2, and K) 120, 130, 140, and 150 may receive y₁, yₖ, y₂, and y_{K}, respectively. yₖ may be represented by,

yₖ=hₖ^{H}x+nₖ, [Equation 1]

where hₖ^{H} denotes a channel vector of a channel that is formed between the base station 110 and the user k 130, nₖ denotes noise added to the user k 130, and x denotes a transmission signal of the base station 110.

The transmission signal x of the base station 110 may be expressed as inner product of the data stream and the beamforming vector selected by the base station 110, as given by,

$$x = {\sum }_{j = 1}^{K} {v}_{j} {s}_{j} , \qquad [ Equation 2 ]$$

where vⱼ denotes the beamforming vector selected by the base station 110 and sⱼ denotes the data stream.

Referring to the above Equation 1 and Equation 2, yₖ may be represented by,

$${y}_{k} = {h}_{k}^{H} {v}_{k} {s}_{k} + {\sum }_{j = 1 , j \neq k}^{K} {h}_{k}^{H} {v}_{j} {s}_{j} + {n}_{k} . \qquad [ Equation 3 ]$$

Referring to the above Equation 3, among signals received by the user k 130, hₖ^{H}vₖsₖ denotes a signal for the user k 130, nₖ denotes noise, and

$${\sum }_{j = 1 , j \neq k}^{K} {h}_{k}^{H} {v}_{j} {s}_{j}$$

denotes interference caused by the user (1) 120, the user (2) 140, and the user K 150.

In this instance, when the user k 130 can be aware of

$${s}_{j} , {\sum }_{j = 1 , j \neq k}^{K} {h}_{k}^{H} {v}_{j} {s}_{j}$$

may be cancelled. Specifically, when the user k 130 can be aware of sⱼ and vⱼ, the interference caused by other users (1, 2, and K) 120, 140, and 150 may be cancelled. Also, when the interference is cancelled, a signal-to-interference and noise ratio (SINR) may increase and thus it is possible to achieve an enhanced data transmission rate.

The above Equation 3 may be alternatively given by,

$${y}_{k} = {h}_{k}^{H} {v}_{k} {s}_{k} + {\sum }_{j < k}^{K} {h}_{k}^{H} {v}_{j} {s}_{j} + {\sum }_{j > k}^{K} {h}_{k}^{H} {v}_{j} {s}_{j} + {n}_{k} . \qquad [ Equation 4 ]$$

Referring to the above Equation 4, when the user k 130 can be aware of sⱼ and vⱼ corresponding to each of the user (1) 120, the user (2) 140, . . . , a user k−1,

$${\sum }_{j < k}^{K} {h}_{k}^{H} {v}_{j} {s}_{j}$$

may be cancelled from the signals received by the user k 130. Thus, the interference caused by the user k 130 may be reduced to

$${\sum }_{j > k}^{K} {h}_{k}^{H} {v}_{j} {s}_{j} .$$

Also, when the user k 130 can be aware of sⱼ and vⱼ corresponding to each of all the other users, the interference caused by the user 130 may be completely cancelled.

For example, when the user k 130 can be aware of a beamforming vector and a data stream corresponding to the user (1) 120, the user k 130 may cancel interference caused by the user (1) 120. Therefore, the user k 130 may need to cooperate with the user (1) 120 in order to be aware of the beamforming vector and the data stream corresponding to the user (1) 120.

Referring to FIG. 2, the user cooperative terminal device includes a signal detector 210, a message generator 220, and a message transfer unit 230.

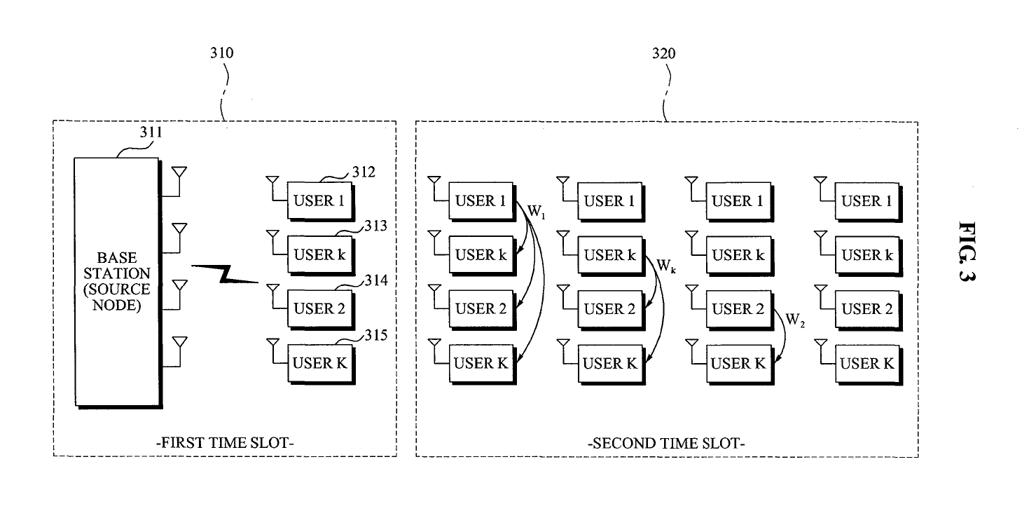

The signal detector 210 may receive a signal transmitted from a source node and detect a received signal. The length of a time slot where the signal detector 210 receives the signal from the source node may be controlled, but descriptions related thereto will be made later in detail with reference to FIG. 3.

The source node is not necessarily limited to a base station and may be a general base station. The source node may receive channel information associated with at least one channel that is formed between the source node and at least one member user, and perform beamforming based on the received channel information. The at least one member user may belong to a predetermined group or may be selected from the base station.

The source node may perform beamforming according to various types of beamforming algorithms, based on channel information that is received from the at least one member user. For example, the source node may perform beamforming using a zero-forcing beamforming algorithm.

The signal detector 210 installed in a terminal device of the user k 130 may receive a transmission signal from the base station via a radio channel. The received signal may be yₖ.

The message generator 220 may cancel interference caused by a neighboring user in the received signal, using a neighboring user message and generate a user message. The neighboring user may decode a received signal of the neighboring user to transfer the neighboring usage message to the message generator 220.

For example, it is assumed that the neighboring user of the user k 130 is the user (1) 120. The received signal of the user (1) 120 may be y₁. The user (1) 120 may detect a data stream s₁ for the user (1) 120 in its received signal and also may decode the data stream s₁ to thereby generate a message w₁ for the user (1) 120. The user (1) 120 may transfer the message w₁ to the user k 130. In this instance, the message w₁ may correspond to the neighboring user message of the user k 130. The user k 130 may cancel, in yₖ, the interference caused by the user (1) 120 corresponding to the neighboring user, using the transferred message w₁.

When the user k 130 receives decoded messages w₁, w₂, and w_{K} from the user (1) 120, the user (2) 140, and the user K 150 respectively, the user k 130 may cancel the interference caused by the user (1) 120, the user (2) 140, and the user K 150 using the transferred messages w₁, w₂, and w_{K}. Therefore, the user k 130 may cancel the interference and then decode a user message wₖ.

Although not illustrated in FIG. 2, a user cooperative terminal device according to example embodiments may further include a channel information receiver that receives, from a neighboring user, channel information associated with a channel that is formed between the neighboring user and a source node. Specifically, a user may be aware of a channel state of the channel formed between the neighboring user and the source node, based on the received channel information.

In this instance, the message generator 220 may generate the user message in which the interference caused by the neighboring user is cancelled, based on the channel information. In particular, the message generator 220 may recognize a beamforming vector, used by the source node, based on the channel information, and may generate the user message in which the interference caused by the neighboring user is cancelled, using the recognized beamforming vector.

For example, referring to FIG. 1 and the above Equation 4, the user k 130 may receive channel information associated with a channel h₁, h₂, or h_{K} that is formed between the base station 110 and the user (1) 120, the user (2) 140, or the user K 150. The user k 130 may be aware of a channel hₖ that is formed between the base station 110 and the user k 130. Therefore, the user k 130 may identify all the channels that are formed between the base station 110 and all the users. Through this, the user k 130 may identify a beamforming vector that is used by the base station 110. Since the user k 130 can be aware of the beamforming vector used by the base station 110 such as vⱼ of the above Equation 4, the user k 130 may cancel interference caused by the neighboring user, using the neighboring user message and the beamforming vector used by the base station 110, and then decode the user message wₖ.

The message generator 220 may generate the user message in which the interference caused by the neighboring user is cancelled, based on information associated with the beamforming vector that is used by the source node. The information is transferred from the source node.

Referring to FIG. 1, the user k 130 may recognize the channel that is formed between the base station 110 and each of the user (1) 120, the user (2) 140, and the user K 150 to thereby identify the beamforming vector used by the base station 110. Also, the user k 130 may receive, from the base station 110, information associated with the beamforming vector used by the base station 110 to thereby identify the beamforming vector used by the base station 110. Even in this case, the user k 130 may cancel the interference caused by the neighboring user and then generate the user message wₖ.

Also, the message transfer unit 230 may transfer the generated user message to the neighboring user or at least one other user excluding the neighboring user.

For example, referring again to FIG. 1, the user k 130 may receive a neighboring user message w₁ from the user (1) 120 corresponding to the neighboring user and generate the user message wₖ in which the interference caused by the user (1) 120 is cancelled, using the neighboring user message w₁. In this instance, the user k 130 may transfer the generated user message wₖ to the other users, the user (2) 140 and the user K 150 that are not the neighboring user. Therefore, the user (2) 140 and the user K 150 may receive w₁ and wₖ and thus may generate messages w₂ and wₖ in which the interference caused by the user (1) 120 and the user k 130 is cancelled.

FIG. 3 illustrates an example of an operation between a base station and users in a first time slot 310 and a second time slot 320 according to example embodiments.

FIG. 3 shows the operation between the base station and the users in the first time slot 310 and the second time slot 320.

In the first time slot 310, a user (1) 312, a user k 313, a user (2) 314, and a user K 315 may receive a transmission signal from a base station 311.

After the user (1) 312, the user k 313, the user (2) 314, and the user K 315 receive the transmission signal from the base station 311 in the first time slot 310, the second time slot 320 may start. In the second time slot 320, each of the user (1) 312, the user k 313, the user (2) 314, and the user K 315 may decode its own message and then transfer the decoded message to a neighboring user or at least one other user excluding the neighboring user.

Specifically, in the second time slot 320, a user 1 may transfer its generated message w₁ to a user k, a user 2, and a user K. The user k may generate wₖ in which interference caused by the user 1 is cancelled, using the transferred w₁.

Also, the user k may transfer the generated wₖ to the user 2 and the user K. In this instance, the user 2 may generate w₂ in which the interference caused by the user 1 and the user k is cancelled, using w₁ and wₖ.

The user 2 may also transfer the generated w₂ to the user K. The user K may generate w_{K} in which the interference caused by the user 1, the user k, and the user 2 is cancelled, using w₁, wₖ, and w₂.

When users may simultaneously perform an operation of receiving a transmission signal from a base station and an operation of transferring/generating a message, there is no need to separate a first time slot and a second time slot. However, it may be physically or practically difficult for the users to simultaneously perform the operation of receiving the transmission signal and the operation of transferring/generating the message. Therefore, there may be a need to control the length of the first time slot or the second time slot.

The length of at least one of the first time slot and the length of the second time slot may be controlled by the base station or users according to a channel state of a channel that is formed between the users. For example, the length of at least one of the first time slot and the second time slot may be controlled to maximize a sum of data transmission rates.

When the length of the first time slot increases, the users may receive more transmission signals from the base station. When the length of the first time slot increases, the length of the second time slot may relatively decrease. The second time slot may correspond to the length of a time for the message transfer and message generation operation between the users. Therefore, when the length of the first time slot is too long, the users may not sufficiently perform the message transfer and message generation operation. Conversely, when the length of the second time slot is too long, the users may not sufficiently receive signals transmitted from the base station. Therefore, the length of the first time slot or the length of the second time slot may be determined based on a channels state of a channel that is formed between the base station and the users, or a channel state of a channel that is formed between the users.

A data transmission rate R_{dl} in the first time slot and a data transmission rate R_{coop} in the second time slot may be represented by,

$$\begin{matrix}{R}_{dl} = E [ {\sum }_{k = 1}^{K} log ( 1 + \frac{{\vert {h}_{k}^{H} {v}_{k} \vert}^{2} {P}_{k}}{{N}_{0} + {\sum }_{j > k}^{K} {\vert {h}_{k}^{H} {v}_{j} \vert}^{2} {P}_{j}} ) ] \\ = E [ {\sum }_{k = 1}^{K} log ( 1 + \frac{{\vert {h}_{k}^{H} {v}_{k} \vert}^{2} \frac{P}{K}}{{N}_{0} + {\sum }_{j > k}^{K} {\vert {h}_{k}^{H} {v}_{j} \vert}^{2} \frac{P}{K}} ) ] \\ ( {P}_{k} = {P}_{j} = \frac{P}{K} ) , and\end{matrix} \\ {R}_{coop} ≡ log ( 1 + \frac{{γ}^{2} δ P}{{N}_{0}} ) , \qquad [ Equation 5 ]$$

where γ denotes a channel gain of the channel formed between the users, P denotes the entire power used in the base station, δ denotes a constant, and N₀ denotes noise.

Rₛᵤₘ may be given by,

$${R}_{sum} = \frac{{T}_{1}}{T} {R}_{dl} , \qquad [ Equation 6 ]$$

where T₁ denotes the length of the first time slot, T₂ denotes the length of the second time slot, and T=T₁+T₂.

In the above Equation 6, the length of the first time slot or the length of the second time slot may be determined to maximize the data transmission rate Rₛᵤₘ in the entire time slot.

As described above, the second time slot may need to have sufficient length in order to smoothly transfer a message among the users.

For example, when T₁R_{dl}≦T₂R_{coop}=(T−T₁)R_{coop} is satisfied, a total data amount that can be transferred in the second time slot may be larger than a total data amount that is transferred in the first time slot. In this case, the message transfer operation may be stably performed among the users in the second time slot. Therefore, the length of the first time slot and the length of the second time slot may be determined to satisfy the condition T₁R_{dl}≦T₂R_{coop}=(T−T₁)R_{coop}, and also to maximize the data transmission rate of the above Equation 6 and satisfy the following Equation 7 as given by,

$${T}_{1} = \frac{{R}_{coop}}{{R}_{dl} + {R}_{coop}} T . \qquad [ Equation 7 ]$$

Referring to the above Equation 5 through Equation 7, the length of the first time slot or the length of the second time slot may be controlled according to the channel state of the channel that is formed between the base station and the users, or the channel state of the channel between the users. Also, the length of the first time slot and the length of the second time slot may be controlled based on the relative size.

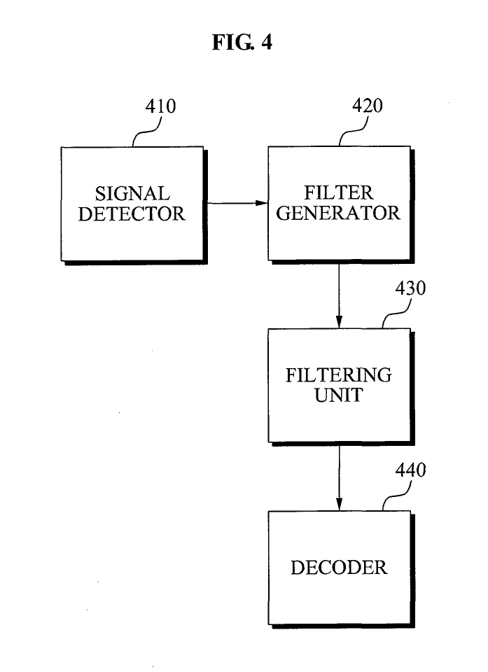

FIG. 4 is a block diagram illustrating an apparatus for receiving a user cooperative signal according to example embodiments.

According to example embodiments, each of users may compress a received signal and transfer the compressed signal to other users. The other users may decompress the received signal and extract an estimate of the original signal. An error may incur between the original signal and the estimate of the original signal. The error may decrease as more bits are used in the compression. This is well specified by a rate distortion theory.

Referring to FIG. 4, the user cooperative signal receiving apparatus includes a signal detector 410, a filter generator 420, a filtering unit 430, and a decoder 440.

The signal detector 410 may receive a signal transmitted from a source node, detect a received signal, and receive a received signal of a neighboring user.

In a first time slot, the signal detector 410 may receive the signal transmitted from the source node and detect the received signal. In a second time slot different from the first time slot, the signal detector 410 may receive the received signal of the neighboring user.

The length of the first time slot or the second time slot may be controlled to maximize a sum of data transmission rates. For example, the length of at least one of the first time slot and the second time slot may be controlled to maximize the sum of data transmission rate according to a channel state. A configuration of controlling the length of the first time slot or the second time slot may be the same as or similar to descriptions made above with reference to FIG. 3 and thus further detailed descriptions will be omitted here.

Hereinafter, with the assumptions that a user 1, a user 2, . . . , a user i, . . . , a user k, . . . , and a user K exist, descriptions will be made. In a case where the user i receives a signal transmitted from the source node and also receives the received signal of the neighboring user, a signal of the user i will be described.

A received signal yₖ of the user k may be represented by,

$${y}_{k} = {h}_{k}^{H} x + {n}_{k} , and \\ x = {\sum }_{j = 1}^{K} {v}_{j} {s}_{j} , \qquad [ Equation 8 ]$$

where hₖ^{H} denotes a channel vector of a channel that is formed between the base station and the user k, nₖ denotes noise added to the user k, x denotes the transmission signal of the base station, vⱼ denotes a beamforming vector selected by the base station, and sⱼ denotes a data stream.

The signal detector 410 installed in the user i may receive the transmission signal from the source node to detect a received signal yᵢ and may also receive a received signal of the user k. In this instance, a signal y′_{i,k} transferred from the user k to the user i may be represented by,

y′_{i,k}=hₖ^{H}xₖ+nₖ+n_{CF}, [Equation 9]

where n_{CF} denotes noise occurring between the user k and the user i.

Referring to the above Equation 9, a variance of n_{NC} may be represented by a variance of yₖ, that is, var(yₖ) and a rate R used for the compression according to the rate distortion theory. Generally, as a cooperative channel formed between users improves, more bits may be used for the compression and thus the variance of n_{CF} may decrease.

In particular, when a signal in the base station or the source node has a Gaussian random variable distribution, the variance of n_{CF} may include the variance of yₖ and thereby be given by,

$$\begin{matrix}Var ( {y}_{k} ) = {h}_{k}^{H} {K}_{x} {h}_{k} + {N}_{0} \\ = \frac{{P}_{TX}}{M} {h}_{k}^{H} {VV}^{H} {h}_{k} + {N}_{0}\end{matrix} \\ {2}^{- R} = {( 1 + \frac{{γ}^{2} {P}_{RX}}{{N}_{0}} )}^{\frac{- {T}_{2}}{{T}_{1}} {λ}_{k}} \\ \begin{matrix}Var ( {n}_{CF} ) = {σ}_{CF , k}^{2} = Var ( {y}_{k} ) {2}^{- R} \\ = ( \frac{{P}_{TX}}{M} {h}_{k}^{H} {VV}^{H} {h}_{k} + {N}_{0} ) \\ {( 1 + \frac{{γ}^{2} {P}_{RX}}{{N}_{0}} )}^{\frac{- {T}_{2}}{{T}_{1}} {λ}_{k}} ,\end{matrix} \qquad [ Equation 10 ]$$

where P_{TX} denotes a transmission power of the base station, P_{RX} denotes a reception power of the user, M denotes a number of antennas installed in the base station, γ denotes a channel gain of a channel that is formed between the users,

$${\sum }_{k = 1}^{K} {λ}_{k} = 1 , {λ}_{k} \geq 0 ,$$

and V denotes a precoding matrix that includes beamforming vectors as a column vector.

Referring to the above Equation 9 and Equation 10, when it is assumed that n_{CF} is a complex Gaussian random variable whose variance is σ_{CF,k}², nₖ+n_{CF} of the above Equation 9 may be replaced by αₖn_{i,k}. In this instance, αₖ may be represented by,

$${α}_{k} = \sqrt{\frac{{N}_{0} + {σ}_{CF , k}^{2}}{{N}_{0}}} . \qquad [ Equation 11 ]$$

Accordingly, after the user i detects the received signal of the user i and receives, from each of all the neighboring users, a received signal thereof, the signal yᵢ of the user i may be represented by,

$$\begin{matrix}{y}_{i} = [ \begin{matrix}{y}_{i , 1}^{′} \\ {y}_{i , 2}^{′} \\ ⋮ \\ {y}_{i} \\ ⋮ \\ {y}_{i , K}^{′}\end{matrix} ] \\ = [ \begin{matrix}{h}_{1} & {h}_{2} & … & {{h}_{K} ]}^{H} x +\end{matrix} [ \begin{matrix}{α}_{1} {n}_{i , 1} \\ {α}_{2} {n}_{i , 2} \\ ⋮ \\ {n}_{i} \\ ⋮ \\ {α}_{K} {n}_{i , K}\end{matrix} ] \\ = Hx + {A}_{i} {n}_{i}\end{matrix} \\ H = [ \begin{matrix}{h}_{1} & {h}_{2} & … & {{h}_{K} ]}^{H} ,\end{matrix} \\ {A}_{i} = [ \begin{matrix}{α}_{1} & 0 & … & 0 \\ 0 & {α}_{2} & … & 0 \\ ⋮ & ⋮ & 1 & ⋮ \\ 0 & 0 & … & {α}_{K}\end{matrix} ] , \\ {n}_{i} = [ \begin{matrix}{n}_{i , 1} \\ {n}_{i , 2} \\ ⋮ \\ {n}_{i} \\ ⋮ \\ {n}_{i , K}\end{matrix} ] . \qquad [ Equation 12 ]$$

The filter generator 420 may generate a filter based on the channel state of the channel that is formed between the neighboring user and the source node.

The filter generator 420 may generate a linear filter that includes a filter according to a minimum mean square error (MMSE) detection scheme or a filter according to a detection scheme using a decorrelator.

When generating the filter according to the MMSE detection scheme, the filter generator 420 may further consider a channel gain of a channel formed with the neighboring user.

For example, the filter according to the MMSE detection scheme may be given by,

$${u}_{i}^{T} = {( {Hv}_{i} )}^{H} {( {N}_{0} {A}_{i} {A}_{i}^{H} + \frac{P}{M} {\sum }_{j = 1 , j \neq i}^{K} {{Hv}_{j} ( {Hv}_{j} )}^{H} )}^{- 1} . \qquad [ Equation 13 ]$$

Also, the filtering unit 430 may filter a received signal and a signal of the neighboring user using the generated filter to thereby extract a user signal.

For example, in view of the user i, the user signal may be a data stream Sᵢ. Using the above Equation 12 and Equation 13, the filtering unit 430 installed in the user i may detect the data stream Sᵢ which is the user signal as given by,

sᵢ=uᵢ^{T}yᵢ [Equation 14]

According to example embodiments, even in the case of a multi-user MIMO communication system, the user i may detect the user signal of the user i through filtering like a single user MIMO communication system. Specifically, according to example embodiments, a point-to-point communication may be enabled.

The decoder 440 may decode the generated user signal to thereby generate a user message.

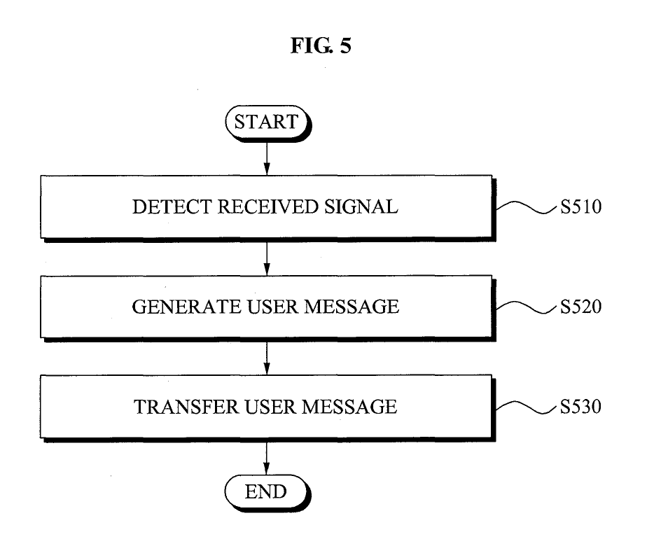

FIG. 5 is a flowchart illustrating a user cooperative communication method according to example embodiments.

Referring to FIG. 5, in operation S510, the user cooperative communication method may receive a signal transmitted from a source node to detect a received signal.

In operation S520, the user cooperative communication method may cancel interference caused by a neighboring user in the received signal, using a neighboring user message to generate a user message. The neighboring user may decode a received signal of the neighboring user to transfer the neighboring user message.

Operation S510 may be an operation of receiving the signal transmitted from the source node to detect the received signal in a first time slot. Operation S520 may be an operation of generating the user message in a second time slot different from the first time slot. The length of at least one of the first time slot and the second time slot may be controlled according to a channel state.

Although not shown in FIG. 5, the user cooperative communication method may further include receiving, from the neighboring user, channel information associated with a channel that is formed between the neighboring user and the source node. Operation S520 may be an operation of generating the user message in which the interference caused by the neighboring user is cancelled, based on the channel information.

According to example embodiments, operation S520 may be an operation of recognizing a beamforming vector used by the source node, based on the channel information to generate the user message in which the interference caused by the neighboring user is cancelled using the recognized beamforming vector.

According to example embodiments, operation S520 may be an operation of generating the user message in which the interference caused by the neighboring user is cancelled based on information associated with the beamforming vector used by the source node. The information is transferred from the source node.

In operation S530, the user cooperative communication method may transfer the user message to the neighboring user, or to at least one other user excluding the neighboring user.

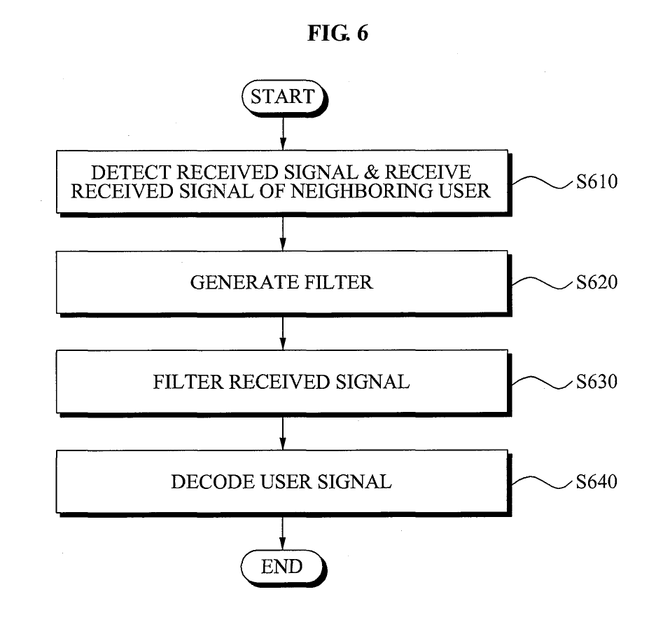

FIG. 6 is a flowchart illustrating a method of receiving a user cooperative signal according to example embodiments.

In operation S610, the user cooperative signal receiving method may receive a signal transmitted from a source node to detect a received signal and receive a received signal of a neighboring user.

According to example embodiments, operation S610 may be an operation of receiving the signal transmitted from the source node to detect the received signal in a first time slot and receiving the receiving signal of the neighboring user in a second time slot different from the first time slot. The length of at least one of the first time slot or the second time slot may be controlled according to a channel state.

In operation S620, the user cooperative signal receiving method may generate a filter based on a channel state of a channel that is formed between the neighboring user and the source node.

According to example embodiments, operation S620 may be an operation of generating a linear filter that includes a filter according to an MMSE detection scheme or a filter according to a detection scheme using a decorrelator.

Also, according to example embodiments, operation S620 may be an operation of generating the filter according to the MMSE detection scheme by further considering a channel gain of a channel formed with the neighboring user.

In operation S630, the user cooperative signal receiving method may filter the received signal and the received signal of the neighboring user using the filter to thereby extract a user signal.

In operation S640, the user cooperative signal receiving method may decode the user signal to generate a user message.

Matters that are shown in FIGS. 5 and 6 but not described have been described above in detail with reference to FIGS. 1 through 4 and thus further detailed descriptions related thereto will be omitted here.

The user cooperative communication method and user cooperative signal receiving method according to example embodiments may be recorded in computer-readable media including program instructions to implement various operations embodied by a computer. The media may also include, alone or in combination with the program instructions, data files, data structures, and the like. The media and program instructions may be those specially designed and constructed for the purposes of example embodiments, or they may be of the kind well-known and available to those having skill in the computer software arts. Examples of computer-readable media include magnetic media such as hard disks, floppy disks, and magnetic tape; optical media such as CD ROM disks and DVD; magneto-optical media such as floptical disks; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of example embodiments, or vice versa.

According to one or more embodiments, there may be provided a user cooperative terminal device and a user cooperative communication method that can cancel interference, caused by a neighboring user, using a neighboring user message that is decoded from the neighboring user to thereby achieve an enhanced data transmission rate.

Also, according to one or more embodiments, there may be provided a user cooperative terminal device and a user cooperative communication method that can receive channel information associated with a channel that is formed between a neighboring user and a source node to thereby effectively cancel interference caused by the neighboring user.

Also, according to one or more embodiments, there may be provided a user cooperative terminal device and a user cooperative communication method that can optimize a ratio of a first time slot for receiving a signal transmitted from a source node and a second time slot for performing a cooperative communication between users to thereby improve a communication performance.

Also, according to one or more embodiments, there may be provided a user cooperative terminal device and a user cooperative communication method that can generate a filter capable of effectively filtering a transferred received signal of a neighboring user and a received signal of a corresponding user to thereby achieve an enhanced data transmission rate.

Although a few embodiments of the present disclosure have been shown and described, the present disclosure is not limited to the described example embodiments. Instead, it would be appreciated by those skilled in the art that changes may be made to these embodiments without departing from the principles and spirit of the disclosure, the scope of which is defined by the claims and their equivalents.

1. A user cooperative terminal device, comprising:
a signal detector configured to receive a signal transmitted from a source node and detect a received signal; and
a message generator configured to:
cancel interference caused by a neighboring user in the received signal, using a neighboring user message; and
generate a user message, the neighboring user decoding a received signal of the neighboring user to transfer the neighboring user message.

2. The device of claim 1, further comprising:
a channel information receiver configured to receive, from the neighboring user, channel information associated with a channel that is formed between the neighboring user and the source node,
wherein the message generator is further configured to generate the user message in which the interference caused by the neighboring user is cancelled, based on the channel information.

3. The device of claim 2, wherein the message generator is further configured to:
recognize a beamforming vector, used by the source node, based on the channel information; and
generate the user message in which the interference caused by the neighboring user is cancelled, using the recognized beamforming vector.

4. The device of claim 2, wherein the message generator is further configured to generate the user message in which the interference caused by the neighboring user is cancelled, based on information associated with a beamforming vector that is used by the source node and the information is transferred from the source node.

5. The device of claim 1, wherein the source node is configured to receive channel information associated with at least one channel that is formed between the source node and at least one member user, and performs beamforming based on the channel information.

6. The device of claim 1, further comprising a message transfer unit configured to transfer the user message to the neighboring user or at least one another user excluding the neighboring user.

7. The device of claim 1, wherein:
the signal detector receives the signal transmitted from the source node to detect the received signal in a first time slot; and
the message generator generates the user message in a second time slot different from the first time slot.

8. The device of claim 7, wherein the length of at least one of the first time slot and the second time slot is controlled according to a channel state.

9. The device of claim 8, wherein the length of at least one of the first time slot and the second time slot is controlled to maximize a sum of data transmission rates.

10. The device of claim 8, wherein the length of the second time slot decreases as a channel gain corresponding to the channel state increases, and the length of the second time slot increases as the channel gain decreases.

11. An apparatus for receiving a user cooperative signal, the apparatus comprising:
a signal detector configured to receive a signal transmitted from a source node, detect a received signal, and receive a received signal of a neighboring user;
a filter generator configured to generate a filter based on a channel state of a channel that is formed between the neighboring user and the source node; and
a filtering unit configured to filter the received signal and the received signal of the neighboring user via the filter and extract a user signal.

12. The apparatus of claim 11, wherein the filter generator is further configured to generate a linear filter that comprises a filter according to a minimum mean square error (MMSE) detection scheme or a filter according to a detection scheme using a decorrelator.

13. The apparatus of claim 12, wherein the filter generator is further configured to generate the filter according to the MMSE detection scheme, further based on a channel gain of a channel formed with the neighboring user.

14. The apparatus of claim 11, further comprising a decoder configured to decode the user signal and generate a user message.

15. The apparatus of claim 11, wherein the signal detector is further configured to:
receive the signal transmitted from the source node to thereby detect the received signal in a first time slot; and
receive the received signal of the neighboring user in a second time slot different from the first time slot.

16. The apparatus of claim 15, wherein the length of at least one of the first time slot and the second time slot is controlled according to a channel state.

17. A user cooperative communication method, comprising:
receiving a signal transmitted from a source node to detect a received signal; and
canceling interference caused by a neighboring user in the received signal, using a neighboring user message to generate a user message, the neighboring user decoding a received signal of the neighboring user to transfer the neighboring user message.

18. The method of claim 17, further comprising:
receiving, from the neighboring user, channel information associated with a channel that is formed between the neighboring user and the source node,
wherein the generating generates the user message in which the interference caused by the neighboring user is cancelled, based on the channel information.

19. The method of claim 18, wherein the generating recognizes a beamforming vector, used by the source node, based on the channel information and generates the user message in which the interference caused by the neighboring user is cancelled, using the recognized beamforming vector.

20. The method of claim 18, wherein the generating generates the user message in which the interference caused by the neighboring user is cancelled, based on information associated with a beamforming vector that is used by the source node and the information is transferred from the source node.

21. The method of claim 17, further comprising transferring the user message to the neighboring user or at least one other user excluding the neighboring user.

22. The method of claim 17, wherein:
the detecting receives the signal transmitted from the source node to detect the received signal in a first time slot; and
the generating generates the user message in a second time slot different from the first time slot.

23. The method of claim 22, wherein the length of at least one of the first time slot and the second time slot is controlled according to a channel state.

24. A method of receiving a user cooperative signal, the method comprising:
receiving a signal transmitted from a source node to detect a received signal and receiving a received signal of a neighboring user;
generating a filter based on a channel state of a channel that is formed between the neighboring user and the source node; and
filtering the received signal and the received signal of the neighboring user via the filter to extract a user signal.

25. The method of claim 24, wherein the generating generates a linear filter that comprises a filter according to an MMSE detection scheme or a filter according to a detection scheme using a decorrelator.

26. The method of claim 25, wherein the generating generates the filter according to the MMSE detection scheme, further based on a channel gain of a channel formed with the neighboring user.

27. The method of claim 24, further comprising decoding the user signal to generate a user message.

28. The method of claim 24, wherein the detecting of the received signal and the receiving of the received signal of the neighboring user receives the signal transmitted from the source node to thereby detect the received signal in a first time slot, and receives the received signal of the neighboring user in a second time slot different from the first time slot.

29. The method of claim 28, wherein the length of at least one of the first time slot and the second time slot is controlled according to a channel state.

30. A non-transitory computer-readable recording medium storing a program for implementing the method of claim 17.
